(19) United States
(12) Patent Application Publication
(10) Pub. No.: US 2025/0048718 A1
(43) Pub. Date: Feb. 6, 2025

(54) METHOD FOR MAKING COMPLEMENTARY FIELD EFFECT TRANSISTOR (CFET) DEVICES INCLUDING SUPERLATTICE ISOLATION LAYER

(71) Applicant: ATOMERA INCORPORATED, LOS GATOS, CA (US)

(72) Inventors: DONGHUN KANG, SAN JOSE, CA (US); MAREK HYTHA, BROOKLINE, MA (US)

(21) Appl. No.: 18/790,385

(22) Filed: Jul. 31, 2024

Related U.S. Application Data
(60) Provisional application No. 63/517,194, filed on Aug. 2, 2023.

(51) Int. Cl. H01L 21/8238; H01L 29/06; H01L 29/423; H01L 29/775; H01L 29/786; H10B 10/00

(52) U.S. Cl. CPC H01L 21/823878; H10B 10/00; H01L 29/0673; H01L 29/42392; H01L 29/775; H01L 29/78696

(57) ABSTRACT

A method for making a semiconductor device may include forming a plurality of complimentary field effect transistors (CFETs). Each CFET may include an n-channel field effect transistor (NFET) and a p-channel field effect transistor (PFET) stacked in vertical relation, with each of the NFET and PFET including spaced apart source and drain regions defining respective channels therebetween. Each CFET may further include a gate overlying both of the channels, and at least one isolation layer between the NFET and the PFET. The at least one isolation layer may include a superlattice including a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

### CROSS-REFERENCE TO RELATED APPLICATIONS

This application claims the benefit of U.S. provisional app. No. 63/517,194 filed Aug. 2, 2023, which is hereby incorporated herein in its entirety by reference.

### TECHNICAL FIELD

The present disclosure generally relates to semiconductor devices, and, more particularly, to complementary field effect transistors (CFET) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include forming a plurality of complimentary field effect transistors (CFETs). Each CFET may include an n-channel field effect transistor (NFET) and a p-channel field effect transistor (PFET) stacked in vertical relation, with each of the NFET and PFET including spaced apart source and drain regions defining respective channels therebetween. Each CFET may further include a gate overlying both of the channels, and at least one isolation layer between the NFET and the PFET. The at least one isolation layer may include a superlattice including a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

In an example embodiment, forming the at least one isolation layer may comprise forming a source isolation layer between the sources of the NFET and PFET, forming a drain isolation layer between the drains of the NFET and PFET, or both. In some embodiments, the n-channel and the p-channel may each comprise a plurality of nanowires. By way of example, the base semiconductor may comprise silicon. Also by way of example, forming the at least one non-semiconductor monolayer may comprise forming oxygen, carbon, or alternating layers of oxygen and carbon monolayers.

In an example implementation, the at least one non-semiconductor monolayer may comprise less than about twenty non-semiconductor layers. In some embodiments, the method may further include forming read/write circuitry coupled to the plurality of CFETs to define a static random access memory (SRAM).

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a perspective view of a complimentary field effect transistor (CFET) in accordance with an example embodiment including source and drain superlattice isolation layers.

FIGS. 5-7 are a series of cross-sectional diagrams taken along line A-A of FIG. 4 illustrating an example method for making the CFET of FIG. 4.

FIG. 8 is a schematic block diagram of a static random access memory (SRAM) incorporating an array of the CFETs of FIG. 4 in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

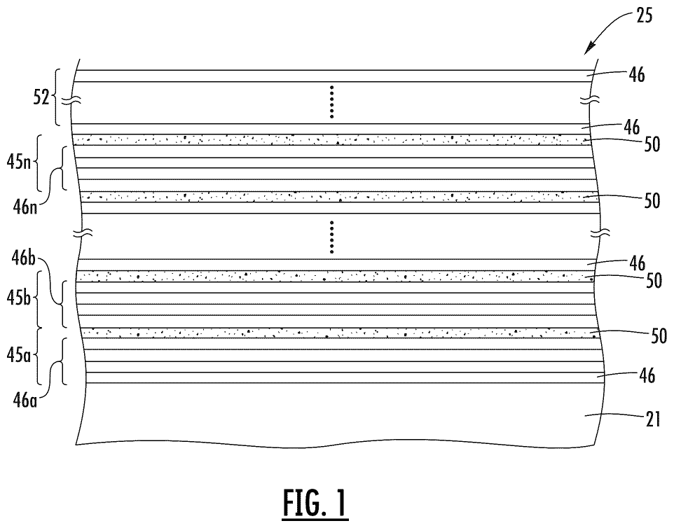

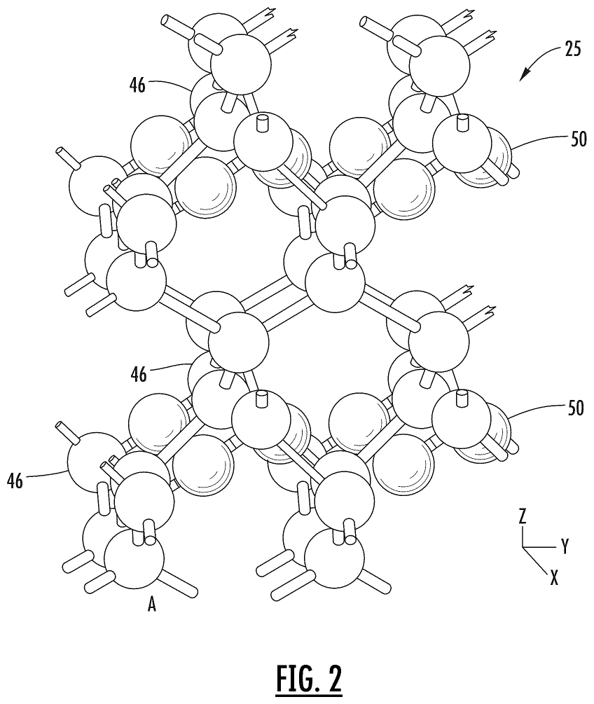

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

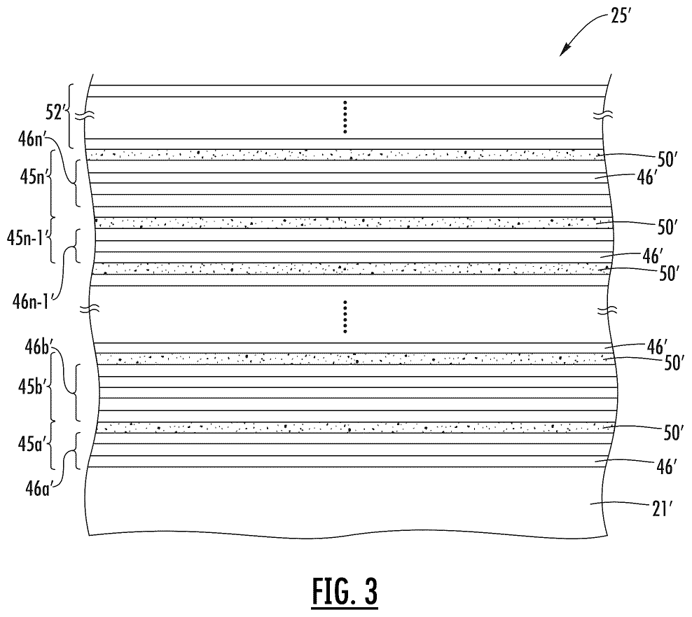

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

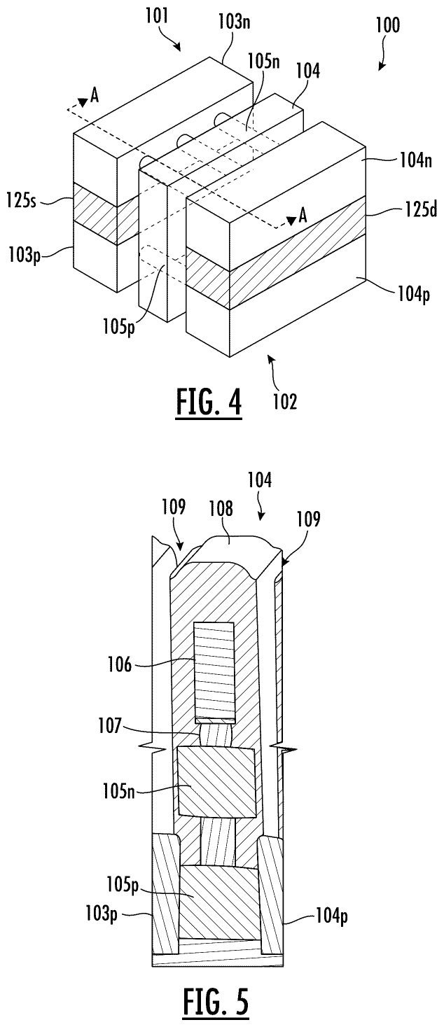

Turning now to FIG. 4, an example complementary field effect transistor (CFET) device 100 advantageously incorporates the above-described superlattices as an isolation layer between vertically stacked NMOS and PMOS transistors. By way of background, there is a general trend in the semiconductor industry toward vertical scaling and 3D structures to allow for increased device densities. However, vertical scaling comes with challenges, such as epitaxial selectivity over multiple different materials.

Typically, CFETs are formed by stacking an NMOS transistor on top of a PMOS transistor, or vice-versa. This configuration advantageously allows for a significant area reduction for future technology nodes. For example, the CFET is a candidate for <2 nm advanced logic devices. However, this configuration may have drawbacks in terms of dopant migration between the different devices based upon their close proximity, which can significantly degrade device performance. The CFET 100 advantageously incorporates the above-described superlattice structures to overcome this technical problem.

More particularly, the CFET 100 illustratively includes an n-channel field effect transistor (NFET) 101 vertically stacked above a p-channel field effect transistor (PFET) 102, although in other embodiments the NFET and PFET may be reversed. The NFET 101 illustratively includes spaced apart source and drain regions 103n, 104n defining an n-channel therebetween. In the illustrated example, the n-channel is defined by a plurality of nanowires 105n. Similarly, the PFET 102 illustratively includes spaced apart source and drain regions 103p, 104p defining a p-channel therebetween, and in this example the p-channel is defined by a plurality of nanowires 105p.

The CFET 100 further illustratively includes a common gate 104 overlying both of the n and p-channels, as well as isolation layer 125s, 125d between the sources 103n, 103p and drains 104n, 104p of the NFET 101 and the PFET 102, respectively. In particular, each of the isolation layers 125s, 125d includes a superlattice, such as those described further above. As noted above, one of the challenges with CFETs is to isolate the NFET and PFET devices electrically. Typical approaches to doing so attempt to use Si-on-SiC, for example. However, SiC is relatively expensive, and may pose challenges in terms of defect elimination.

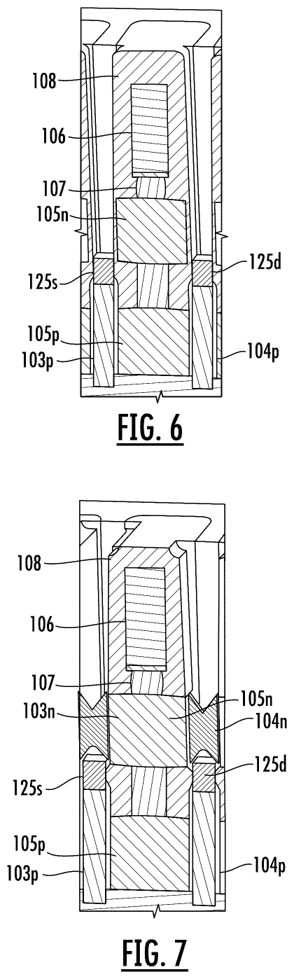

The present approach advantageously helps overcome these technical challenges by utilizing the above-described dopant blocking characteristics of MST materials to provide isolation between the sources 103n, 103p and drains 104n, 104p of the NFET 101 and the PFET 102. An example approach for fabricating CFETs 100 is now further described with reference to FIGS. 5-8. Fabrication begins with formation of the nanosheets 105n, 105p and gate 104, which illustratively includes a gate electrode 106 (e.g., polysilicon) and gate dielectric 107, as well as a spacer 108 (e.g., SiN). Trenches 109 may then be formed on opposite sides of the gate 104 to allow for epitaxial growth of the PFET 102 source and drain regions 103p, 104p (FIG. 5). The superlattice isolation layers 125s, 125d are then epitaxially grown at the bottom of the trenches 109 over the source and drain regions 103p, 104p (FIG. 6), as discussed further above.

By way of example, the MST film used in the isolation layers 125s, 125d may include non-semiconductor monolayers 50 of oxygen, carbon, or alternating layers of carbon and oxygen, for example. However, other non-semiconductor materials may be used in different embodiments, such as those noted above (e.g., nitrogen, etc.). By way of example, a number of carbon and/or oxygen monolayers included within the MST film may be in a range from 1-20 monolayers. In all of these example configurations, the MST layers advantageously provide desired dopant diffusion blocking from both NMOS and PMOS source/drain regions 103n, 103p and 104n, 104p, as well as electrical isolation.

After formation of the superlattice isolation layers 125s, 125d, the NFET 101 source/drain epitaxy may be performed to grow the source 103n and drain 104n, as seen in FIG. 7. Further processing may then be performed to form appropriate contacts/vias, as will be appreciated by those skilled in the art. For example, source/drain contacts (e.g., metal contacts) for the bottom transistor (PFET in the present example) may be formed after the source and drain 111p, 112p epitaxial deposition by using wafer bonding.

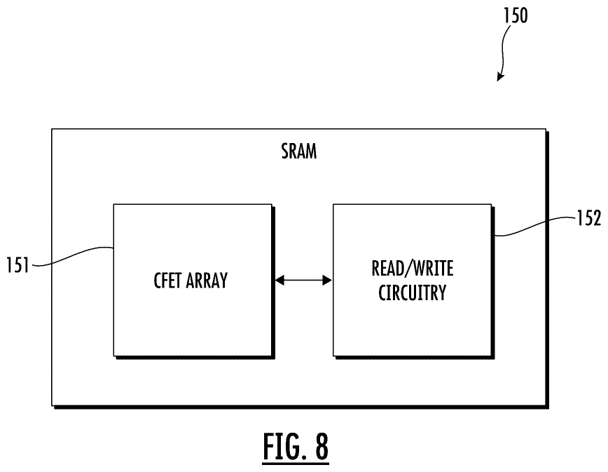

Moreover, in one example implementation illustrated in FIG. 8, an array 151 of the CFETs 100 may be incorporated in a memory device. For example, the array 151 may be coupled with read/write circuitry 152 to define a static random access memory (SRAM) 150. The array 151 may similarly be used in other memory devices as well, as will be appreciated by those skilled in the art.

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A method for making a semiconductor device comprising:
forming a plurality of complimentary field effect transistors (CFETs) each CFET comprising
an n-channel field effect transistor (NFET) and a p-channel field effect transistor (PFET) stacked in vertical relation, each of the NFET and PFET comprising spaced apart source and drain regions defining respective channels therebetween;
a gate overlying both of the channels; and
at least one isolation layer between the NFET and the PFET and comprising a superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

2. The method of claim 1 wherein forming the at least one isolation layer comprises:
forming a source isolation layer between the source regions of the NFET and PFET; and
forming a drain isolation layer between the drain regions of the NFET and PFET.

3. The method of claim 1 wherein forming the at least one isolation layer comprises forming a source isolation layer between the source regions of the NFET and PFET.

4. The method of claim 1 wherein forming the at least one isolation layer comprises forming a drain isolation layer between the drain regions of the NFET and PFET.

5. The method of claim 1 wherein each of the channels comprises a plurality of nanowires.

6. The method of claim 1 wherein the base semiconductor portion comprises silicon.

7. The method of claim 1 wherein the at least one non-semiconductor monolayer comprises oxygen.

8. The method of claim 1 wherein the at least one non-semiconductor monolayer comprises carbon.

9. The method of claim 1 wherein forming the at least one non-semiconductor monolayer comprises forming alternating layers of oxygen and carbon monolayers.

10. The method of claim 1 wherein the at least one non-semiconductor monolayer comprises less than about twenty non-semiconductor layers.

11. The method of claim 1 further comprising forming read/write circuitry coupled to the plurality of CFETs to define a static random access memory (SRAM).

12. A method for making a semiconductor device comprising:
forming a plurality of complimentary field effect transistors (CFETs), each CFET comprising
an n-channel field effect transistor (NFET) and a p-channel field effect transistor (PFET) stacked in vertical relation, each of the NFET and PFET comprising spaced apart source and drain regions defining respective channels therebetween, and each of the channels comprising a plurality of nanowires;
a gate overlying both of the channels;
a source isolation layer between the source regions of the NFET and PFET; and
a drain isolation layer between the drain regions of the NFET and PFET;
the source isolation layer and the drain isolation layer each comprising a superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

13. The method of claim 12 wherein the base semiconductor portion comprises silicon.

14. The method of claim 12 wherein the at least one non-semiconductor monolayer comprises at least one of oxygen and carbon.

15. The method of claim 12 further comprising forming read/write circuitry coupled to the plurality of CFETs to define a static random access memory (SRAM).

16. A method for making a semiconductor device comprising:
forming a plurality of complimentary field effect transistors (CFETs) each CFET comprising
an n-channel field effect transistor (NFET) and a p-channel field effect transistor (PFET) stacked in vertical relation, each of the NFET and PFET comprising spaced apart source and drain regions defining respective channels therebetween;
a gate overlying both of the channels; and
at least one isolation layer between the NFET and the PFET and comprising a superlattice comprising a plurality of stacked groups of layers, each group of layers comprising a plurality of stacked base silicon monolayers defining a base silicon portion, and at least one non-semiconductor monolayer constrained within a crystal lattice of adjacent base silicon portions and comprising at least one of carbon and oxygen.

17. The method of claim 16 wherein forming the at least one isolation layer comprises:
forming a source isolation layer between the source regions of the NFET and PFET; and
forming a drain isolation layer between the drain regions of the NFET and PFET.

18. The method of claim 16 wherein each of the channels comprises a plurality of nanowires.

19. The method of claim 16 wherein forming the at least one non-semiconductor monolayer comprises forming alternating layers of oxygen and carbon monolayers.

20. The method of claim 16 further comprising forming read/write circuitry coupled to the plurality of CFETs to define a static random access memory (SRAM).
